(19) United States
(12) Patent Application Publication
(10) Pub. No.: US 2009/0038171 A1
(43) Pub. Date: Feb. 12, 2009

(54) ALIGNMENT TOOL FOR ASSEMBLY OF MICROPROCESSOR BOARD TO SERVER CHASSIS

(75) Inventors: Eric A. Eckberg, Rochester, MN (US); Seth D. Lewis, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/835,467

(22) Filed: Aug. 8, 2007

(51) Int. Cl. G01D 21/00; H05K 7/14

(52) U.S. Cl. 33/645; 33/613; 361/683; 361/726

(57) ABSTRACT

An alignment tool for assembly of a microprocessor board to a server chassis includes a peg hole portion receptive of a first peg of the server chassis and at least one filler tab insertable between the first peg and a secondary hole of the microprocessor board. The alignment tool further includes an orientation hole portion receptive of a second peg of the server chassis, and connected to the peg hole portion. A method of aligning the server chassis to the microprocessor board utilizing the alignment tool includes placing the alignment tool with the peg hole portion over the first peg and an orientation hole portion over a second peg. The microprocessor board, including a secondary hole, is placed over the server chassis such that the secondary hole is placed over the first peg. At least one filler tab of the alignment tool is inserted into a gap between the first peg and the secondary hole.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to assembly of electronic components, and particularly to alignment of a microprocessor board to a server chassis.

2. Description of Background

Components of electronic assemblies are often located for assembly with a peg-and-hole method. A first component is provided with two or more locating pegs and a second component is provided with two holes that correspond to the peg locations. When the holes are aligned with the pegs, the pegs are passed into the holes thus aligning the second component with the first component.

A first hole of the two holes is often of a diameter just large enough for the peg to enter and thus acts as a datum hole. A second hole is of a larger diameter to accommodate tolerances in the manufacture of the first and second components among other tolerances. Because the second hole is oversized, it allows for angular movement of the second component once it is located relative to the first component, which may not be beneficial when attempting to precisely align the two components. In some instances, the components may be aligned by using a datum hole and replacing the oversized hole with a slot, but in many cases a slot is not desired (due to manufacturing cost or other concerns).

### SUMMARY OF THE INVENTION

The shortcomings of the prior art, that can only use two holes for alignment, are overcome and additional advantages are provided through the provision of an alignment tool for assembly of a microprocessor board to a server chassis including a peg hole portion receptive of a first peg of the server chassis, an orientation hole portion receptive of a second peg of the server chassis and at least one filler tab insertable between the first peg and a secondary hole of the microprocessor board.

A method of aligning a server chassis to a microprocessor board includes placing the microprocessor board, which includes a datum hole and the secondary hole, over the server chassis that a first peg extends through the secondary hole. The alignment tool is placed over the chassis pegs, and when the board is then placed on the chassis, the filler tabs are inserted into a gap between the first peg and the secondary hole.

### TECHNICAL EFFECTS

As a result of the summarized invention, technically we have achieved a solution which is capable of precisely locating components a microprocessor board relative to a server chassis utilizing a peg and hole method without variation in relative angular position between the two components. This method is especially beneficial when alternative means for locating, such as a slotted hole or a diamond pin is not practical or feasible.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 is a plan view of an embodiment of a microprocessor board installed on a server chassis;

FIG. 2 illustrates one example of an alignment tool; and

FIG. 3 is a perspective view illustrating placement of an alignment tool of FIG. 2 on a first component;

FIG. 4 is a perspective view illustrating placement of a second component over an alignment tool of FIG. 2; and

FIG. 5 is a detail section view of the utilization of the alignment tool of FIG. 2. installed on a peg.

The detailed description explains the preferred embodiments of the invention, together with advantages and features, by way of example with reference to the drawings.

### DETAILED DESCRIPTION OF THE INVENTION

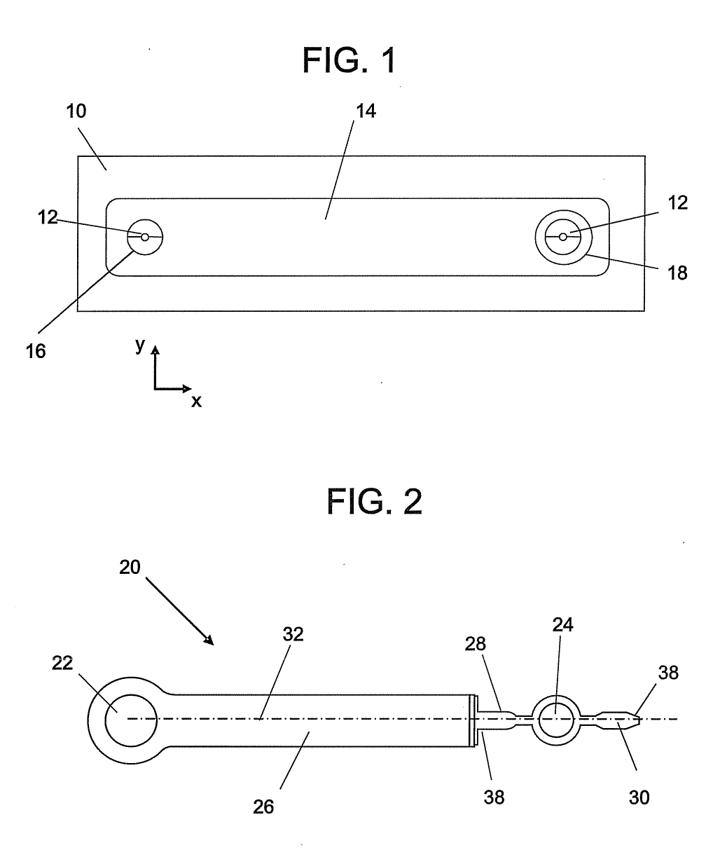

Turning now to the drawings in greater detail, it will be seen that in FIG. 1 there is a first component, in this embodiment a server chassis 10. The server chassis 10 includes two pegs 12 which extend from the server chassis 10. In this embodiment, the pegs 12 are substantially cylindrical in shape and are substantially equal in size. It is to be appreciated, however, that other peg shapes and relative sizes are contemplated within the present scope. A mating part, microprocessor board 14, is configured with a datum hole 16 and a secondary hole 18. The datum hole 16 is sized for a close fit to the peg 12 to position the microprocessor board 14 in an x and y direction as shown in FIG. 1. The secondary hole 18 is oversized relative to the peg 12 to compensate for tolerances in, for example, manufacture of the server chassis 10 and manufacture of the microprocessor board 14. The microprocessor board 14 is assembled to the server chassis 10 by placing the datum hole 16 and the secondary hole 18 over the pegs 12.

To ensure proper alignment between the server chassis 10 and the microprocessor board 14 during assembly, an alignment tool 20, as shown in FIG. 2, is utilized. The alignment tool 20 includes an orientation hole 22 and a peg hole 24 with a strap portion 26 disposed between the orientation hole 22 and the peg hole 24. The peg hole 24 is configured and sized for a close fit to one of the pegs 12, while the orientation hole 22 is oversized relative to the pegs 12. The alignment tool 20 also includes a first filler tab 28 and a second filler tab 30 which extend substantially parallel to a hole axis 32. The first filler tab 28 is disposed connecting the peg hole 24 to the strap portion 26, and the second filler tab 30 extends from a substantially opposite portion of the peg hole 24 as the first filler tab 28.

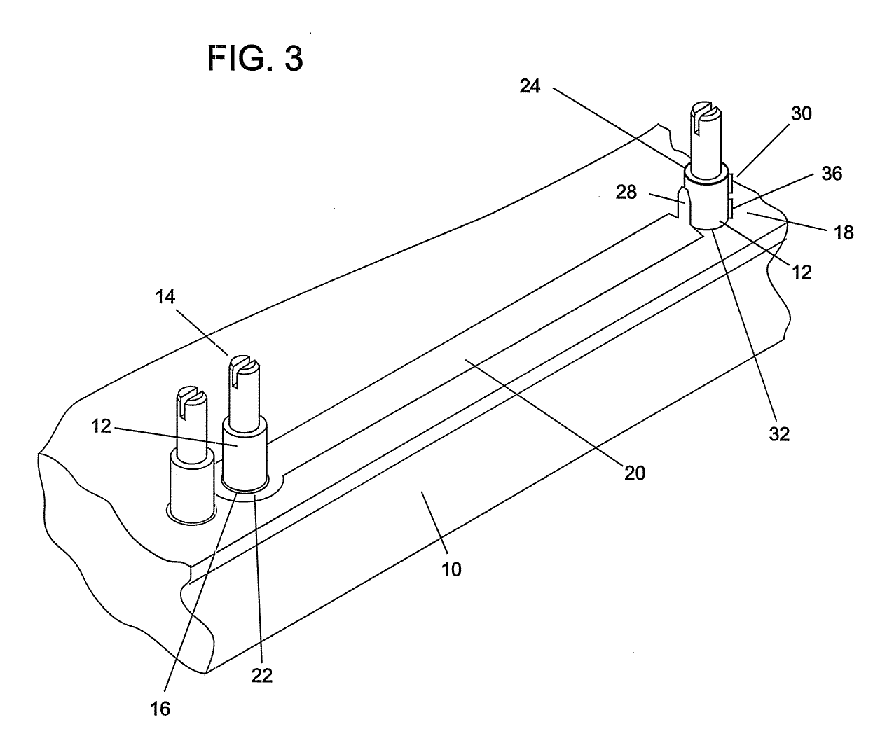

An assembly process utilizing the alignment tool 20 is shown in FIG. 3. The alignment tool 20 is placed over the pegs 12, with the peg hole 24 over the same peg 12 as the secondary hole 18 in the microprocessor board 14. The orientation hole 22 in the alignment tool 20 is placed over a second peg 12. The orientation hole 22 is utilized to ensure that the filler tabs 28, 30 are in correct circumferential locations with respect to the peg 12, perpendicular to a line between the first and second pegs 12.

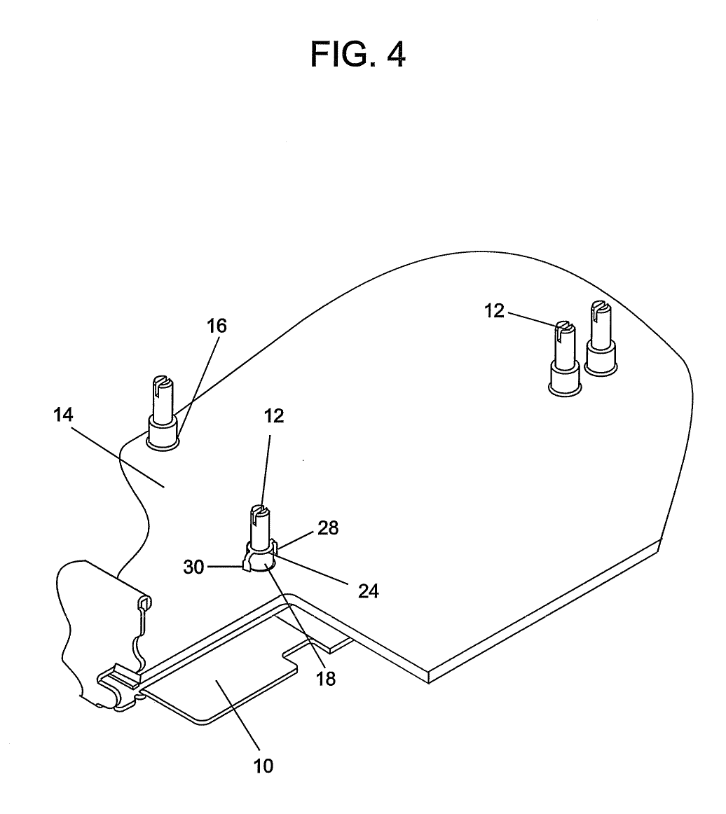

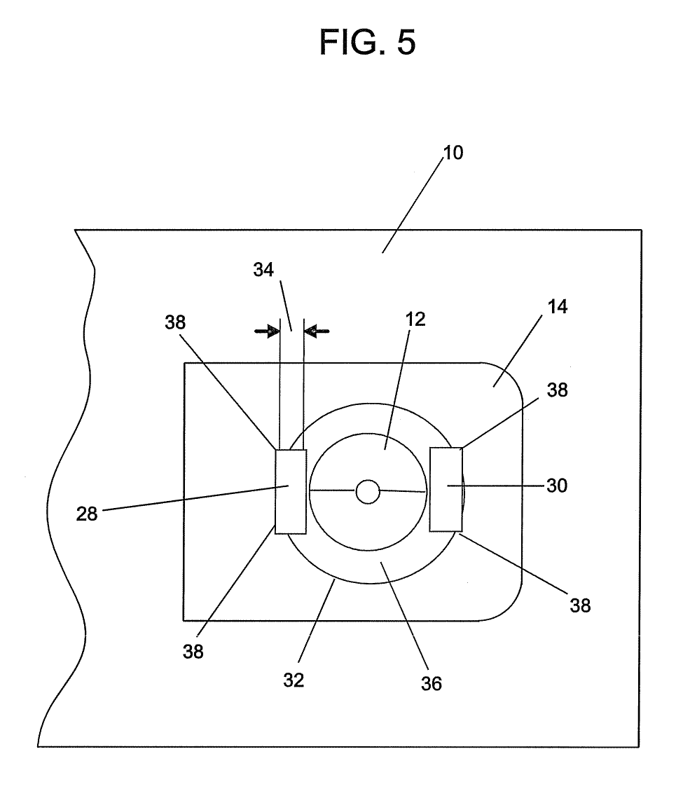

As shown in FIG. 4, the microprocessor board 14 is then placed over the server chassis 10 as described above with the datum hole 16, the secondary hole 18 and, in some embodiments, a third hole 44 over the pegs 12. The filler tabs 28, 30 are folded downward toward the peg 12 at the secondary hole 18 and fill the gap between the peg 12 and an edge 32 of the secondary hole 18 shown in FIG. 5. The thickness 34 of the filler tabs 28, 30 in this embodiment, is equal to a minimal radial gap 36 between the edge 32 and the peg 12. In some embodiments, as shown in FIG. 5, corners 38 of the filler tabs 28, 30 bend slightly to conform to the shape of the gap 36, which in this case is an arc. This provides a self-centering capability between the hole and slot. In one embodiment, the filler tabs 28, 30 are formed from a flexible material, for example, PVC insulator, in order to be more easily insertable into the gap 36. By inserting the filler tabs 28, 30 between the edge 32 and the peg 12, the secondary hole 18 is centered on the peg 12, thus preventing misalignment between the peg 12 and the secondary hole 18 in the X direction, while allowing clearance tolerance in the Y direction.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. An alignment tool for assembly of a microprocessor board to a server chassis comprising:
a peg hole portion receptive of a first peg of the server chassis;
at least one filler tab insertable between the first peg and a secondary hole of the microprocessor board; and
an orientation hole portion receptive of a second peg of the server chassis, and operably connected to the peg hole portion.

2. The alignment tool of claim 1 wherein the at least one filler tab is two filler tabs.

3. The alignment tool of claim 1 wherein a thickness of each filler tab is substantially equal to a minimum radial gap between the first peg and the secondary hole.

4. The alignment tool of claim 1 wherein the at least one filler tabs are disposed and configured substantially perpendicular to a line between the first peg and the second peg.

5. The alignment tool of claim 1 wherein the at least on filler tab has flexible corners.

6. A method of aligning a server chassis to a microprocessor board comprising:
placing an alignment tool over the server chassis, the alignment tool including:
a peg hole portion receptive of a first peg of the server chassis;
at least one filler tab insertable between the first peg and a secondary hole of the microprocessor board; and
an orientation hole portion receptive of a second peg of the server chassis.
placing the microprocessor board, including a secondary hole, over the alignment tool, such that the first peg extends through the secondary hole; and
inserting the at least one filler tab into a gap between the first peg and the secondary hole.

7. The alignment tool of claim 6 wherein the at least one filler tab is two filler tabs.

8. The alignment tool of claim 6 wherein a thickness of each filler tab is substantially equal to a minimum radial gap between the first peg and the secondary hole.

9. The alignment tool of claim 6 wherein the at least one fuller tabs are disposed and configured substantially perpendicular to a line between the first peg and the second peg.

10. The alignment tool of claim 6 wherein the at least on filler tab has flexible corners.
